(19) United States
(12) Patent Application Publication
(10) Pub. No.: US 2019/0049785 A1
(43) Pub. Date: Feb. 14, 2019

(54) LIQUID CRYSTAL DISPLAY PANEL AND LIQUID CRYSTAL DISPLAY DEVICE

(71) Applicants: HKC Corporation Limited, Shenzhen City, Guangdong (CN); Chongqing HKC Optoelectronics Technology Co. Limited, Chongqing (CN)

(72) Inventor: En-Tsung CHO, Chongqing (CN)

(21) Appl. No.: 15/556,019

(22) PCT Filed: Jul. 7, 2017
(86) PCT No.: PCT/CN2017/092145

§ 371 Date: Sep. 6, 2017

(30) Foreign Application Priority Data
Feb. 27, 2017 (CN) 201710108290.5

(51) Int. Cl. G02F 1/1335; G02F 1/1333; G01K 13/00; H01L 27/12

(52) U.S. Cl. CPC G02F 1/133528; G02F 1/133382; H01L 27/1214; G02F 1/133514; G02F 1/133602; G01K 13/00

(57) ABSTRACT

The present application relates to a liquid crystal display panel and a liquid crystal display device. The liquid crystal display panel comprises: a first substrate having an outer surface; a first polarizer disposed on the outer surface of the first substrate; a second substrate disposed opposite the first substrate and having an outer surface; a second polarizer disposed on the outer surface of the second substrate; and a temperature sensor disposed on the periphery of the outer surface of the first substrate or embedded within the first substrate.

### FIELD

The present application relates to an embedded temperature sensor, and in particular, to a liquid crystal display panel and a liquid crystal display device.

### RELATED ART

A liquid crystal display panel generally consists of a color filter (CF) substrate, a thin film transistor (TFT) array substrate, and a liquid crystal (LC) layer disposed between the two substrates. An operating principle of the liquid crystal display panel is as follows: a drive voltage is applied across two glass substrates to control rotation of liquid crystal molecules of the liquid crystal layer, so as to refract light from a backlight module to generate an image. According to different liquid crystal orientations, mainstream liquid crystal display panels currently available in the market may be classified into the following types: vertical alignment (VA) type, twisted nematic (TN) or super twisted nematic (STN) type, in-plane switching (IPS) type, and fringe field switching (FFS) type.

The VA-mode type of liquid crystal displays include, for example, a patterned vertical alignment (PVA) liquid crystal display or a multi-domain vertical alignment (MVA) liquid crystal display device. The PVA type uses a fringe field effect and a compensation plate to achieve a wide viewing angle. The MVA type divides a pixel into a plurality of regions, and makes liquid crystal molecules in different regions tilt towards different directions by using protrusions or a particular pattern structure, so as to achieve a wide viewing angle and enhance the transmittance.

A thermally sensitive resistance, also referred to as a thermistor, is a resistor highly sensitive to temperature. The internal resistance value of this component changes greatly as the temperature changes. A principle of a thermocouple is the Seebeck effect, also referred to as a thermoelectric effect, occurring in the following situation: metals of different types have a different number of free electrons; and when two metals are joined to form a loop, the free electrons at a joint will move with a change in temperature; and then a potential difference is generated between the metals. The extent of the potential difference depends on the contact area, the temperature difference, and the metal type. When two ends are at the same temperature, thermo-electromotive forces produced at the ends are the same; and therefore no current flows in the loop. When a temperature difference exists between the two ends, the thermo-electromotive forces are different; as a result, a current is produced, flowing from the end with a high electromotive force to the end with a low electromotive force.

The electrical conductivity of a semiconductor material is susceptible to temperature changes: accordingly, the electrical conductivity of an integrated circuit (IC) made of the semiconductor material is also susceptible to temperature changes. Theoretically, a diode formed on a pn junction may be used as a temperature sensing component. In reality, however, the pn junction is forward biased and a reverse saturation current IS changes with a change in temperature. The pn junction is, therefore, rarely used alone as a sensing component. Instead, the pn junction is mostly used as a type of transistor. An IC type circuit made by combining a temperature sensing transistor with an amplification circuit is referred to as a temperature sensing IC. However, the temperature inside the liquid crystal display panel cannot be effectively controlled when in use, thus resulting in delayed liquid crystal response and image retention.

### SUMMARY

In order to solve the foregoing technical problems, an object of the present application is to provide an embedded temperature sensor, and in particular, a liquid crystal display panel and a liquid crystal display device.

The objective of the present application and the solution of the technical problems are achieved by adopting the following technical solution. A liquid crystal display panel according to the present application comprises: a first substrate having an outer surface; a first polarizer disposed on the outer surface of the first substrate; a second substrate disposed opposite the first substrate and having an outer surface; a second polarizer disposed on the outer surface of the second substrate; and a temperature sensor disposed on the periphery of the outer surface of the first substrate or embedded within the first substrate.

The objective of the present application and the solution of the technical problems may be further achieved by adopting the following technical solutions.

In an embodiment of the present application, when the temperature sensor is disposed on the periphery of the outer surface of the first substrate, the temperature sensor is located between the first substrate and the first polarizer.

In an embodiment of the present application, the temperature sensor is a metal heater containing indium gallium zinc oxide.

In an embodiment of the present application, the temperature sensor is made of a metal material containing graphene.

In an embodiment of the present application, the first substrate is a thin film transistor substrate.

In an embodiment of the present application, the second substrate is a color filter substrate.

In an embodiment of the present application, the liquid crystal display panel further includes a liquid crystal layer disposed between the first substrate and the second substrate.

Another object of the present application is to provide a liquid crystal display device, comprising a backlight module; and a liquid crystal display panel, comprising: a first substrate having an outer surface; a first polarizer disposed on the outer surface of the first substrate; a second substrate disposed opposite the first substrate and having an outer surface: a second polarizer disposed on the outer surface of the second substrate; and a temperature sensor disposed on the periphery of the outer surface of the first substrate or embedded within the first substrate, wherein when the temperature sensor is disposed on the periphery of the outer surface of the first substrate, the temperature sensor is located between the first substrate and the first polarizer.

The objective of the present application and the solution of the technical problems may be further achieved by adopting the following technical solutions.

In an embodiment of the present application, the temperature sensor is a metal heater containing indium gallium zinc oxide.

In an embodiment of the present application, the temperature sensor is made of a metal material containing graphene.

In an embodiment of the present application, the first substrate is a thin film transistor substrate.

In an embodiment of the present application, the second substrate is a color filter substrate.

In an embodiment of the present application, the liquid crystal display panel further includes a liquid crystal layer disposed between the first substrate and the second substrate.

Still another object of the present application is to provide a liquid crystal display device, comprising a backlight module and a liquid crystal display panel, comprising: a thin film transistor substrate having an outer surface; a first polarizer disposed on the outer surface of the thin film transistor substrate; a color filter substrate disposed opposite the thin film transistor substrate and having an outer surface; a second polarizer disposed on the outer surface of the color filter substrate; and a temperature sensor disposed on the periphery of the outer surface of the thin film transistor substrate or embedded within the thin film transistor substrate. The temperature sensor is a metal heater containing indium gallium zinc oxide or is made of a metal material containing graphene. The temperature sensor is disposed on the periphery of the outer surface of the thin film transistor substrate or embedded within the thin film transistor substrate in a continuously bending manner. When the temperature sensor is disposed on the periphery of the outer surface of the thin film transistor substrate, the temperature sensor is located between the thin film transistor substrate and the first polarizer.

The present application can effectively provide information regarding ambient temperature, and can effectively control the liquid crystal temperature, avoiding delayed liquid crystal response and image retention in a low-temperature environment.

### BRIEF DESCRIPTION OF THE DRAWINGS

FIG. 1 is a schematic diagram of an exemplary liquid crystal display panel having an indium-tin-oxide heater.

FIG. 2a is a schematic diagram of exemplary process steps of evaluating a thermally sensitive resistance system.

FIG. 2b is an exemplary flicker comparison between having and not having a temperature compensation system.

FIG. 3 is a schematic diagram of a liquid crystal display panel integrated with a metal-sheet type thermally sensitive sensor according to an embodiment of the present application.

FIG. 4 is a schematic diagram of width of a metal sheet of a fabricated thermally sensitive sensor according to an embodiment of the present application.

FIG. 5a is a circuit diagram of a thermally sensitive sensor according to an embodiment of the present application.

FIG. 5b is an illustration of experimental output values from four sensors using a voltage-temperature curve according to an embodiment of the present application.

FIG. 6 is a schematic diagram of a temperature display according to an embodiment of the present application.

FIG. 7a is a schematic diagram of a liquid crystal display panel according to an embodiment of the present application.

FIG. 7b is a schematic diagram of a liquid crystal display panel according to another embodiment of the present application.

FIG. 8 is a schematic diagram of a resistance according to an embodiment of the present application.

FIG. 9 is a schematic diagram of a liquid crystal display panel according to still another embodiment of the present application.

FIG. 10 is a schematic diagram of integrating a temperature sensor into a liquid crystal display according to an embodiment of the present application.

### DETAILED DESCRIPTION

The following embodiments are described with reference to the accompanying drawings, illustrating specific embodiments for implementing the present application. Directional terms mentioned in the present application, such as upper, lower, front, rear, left, right, inner, outer, and sides, are used with reference to the accompanying drawings. Therefore, the directional terms are used to describe and for the understanding of the present application, and are not intended to limit the present application.

The accompanying drawings and descriptions are to be considered illustrative rather than restrictive in essence. In the drawings, structurally similar elements are indicated by identical numerals. In addition, for ease of understanding and description, the size and thickness of each component are arbitrarily shown in the accompanying drawings; and the present application is not limited thereto.

In the drawings, the thicknesses of a layer, a film, a panel, and a region are enlarged for the sake of clarity. In the drawings, the thicknesses of some layers and regions are enlarged for ease of understanding and description. It can be understood that when a component such as a layer, a film, a region, or a substrate is said to be located “on” another component, the component may be directly located on the other component or there may be an intervening component.

In addition, unless otherwise expressly stated to the contrary herein, the term “include” will be understood to refer to including the components, and not excluding any other component. Further, the term “on” herein refers to being above or below a target component and not necessarily on the top thereof in the gravitational direction.

To further explain the technical means used in the present application to achieve the predetermined objectives and the effect of the technical means, a liquid crystal display panel and a liquid crystal display device according to the present application, and specific implementations, structures, features, and effects thereof are described in detail below with reference to the accompanying drawings and preferred embodiments.

The liquid crystal display device of the present application may include a backlight module and a liquid crystal display panel. The liquid crystal display panel may include a thin film transistor (TFT) substrate, a color filter (CF) substrate, and a liquid crystal layer formed between the two substrates.

In an embodiment of the present application, the liquid crystal display panel of the present application may be a curved display panel; and the liquid crystal display device of the present application may also be a curved display device.

In an embodiment of the present application, a thin film transistor (TFT) and a color filter (CF) of the present application may be formed on the same substrate.

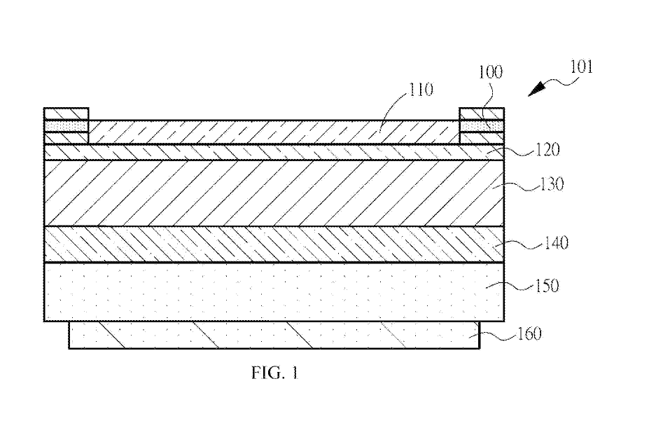

FIG. 1 is a schematic diagram of an exemplary liquid crystal display panel having an indium-tin-oxide heater. Please refer to FIG. 1 for a liquid crystal display panel 101, comprising: a first substrate 130 having an outer surface; a first polarizer 110 disposed on the outer surface of the first substrate 130; a flexible circuit board 100 disposed on the periphery of the first polarizer 110; a second substrate 150 disposed opposite the first substrate 130 and having an outer surface; a second polarizer 160 disposed on the outer surface of the second substrate 150; a liquid crystal layer 140 disposed between the first substrate 130 and the second substrate 150; and a temperature sensor 120 disposed between the first substrate 130 and the first polarizer 110, wherein the temperature sensor 120 is an indium-tin-oxide heater.

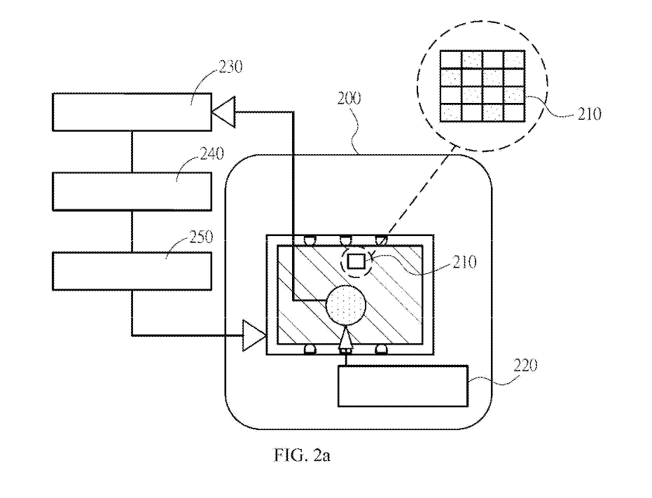

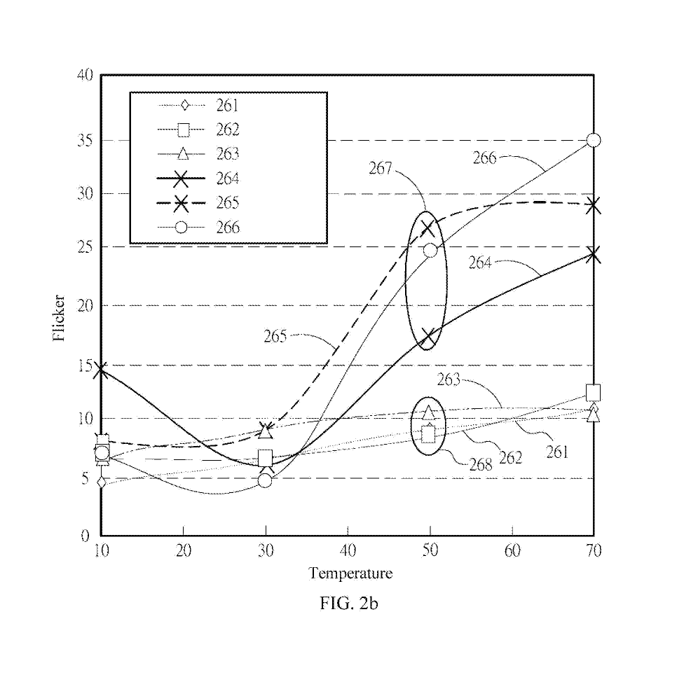

FIG. 2a is a schematic diagram of exemplary process steps of evaluating a thermally sensitive resistance system. Please refer to FIG. 2a. In a thermometer 200, the process steps of evaluating a thermally sensitive resistance system include: displaying a reading 210 on the thermometer; pointing an optical probe 220; and using a scintillometer 230, an operator 240, and a tuner 250.

FIG. 2b is an exemplary flicker comparison between having and not having a temperature compensation system. Please refer to FIG. 2b. For controlling temperature using the temperature compensation system, a relationship between flicker and temperature is shown (as is shown in FIG. 2b, indicated by the six curves 261, 262, 263, 264, 265, and 266), wherein a coordinate position 267 without a feedback control and a coordinate position 268 with a feedback control are included.

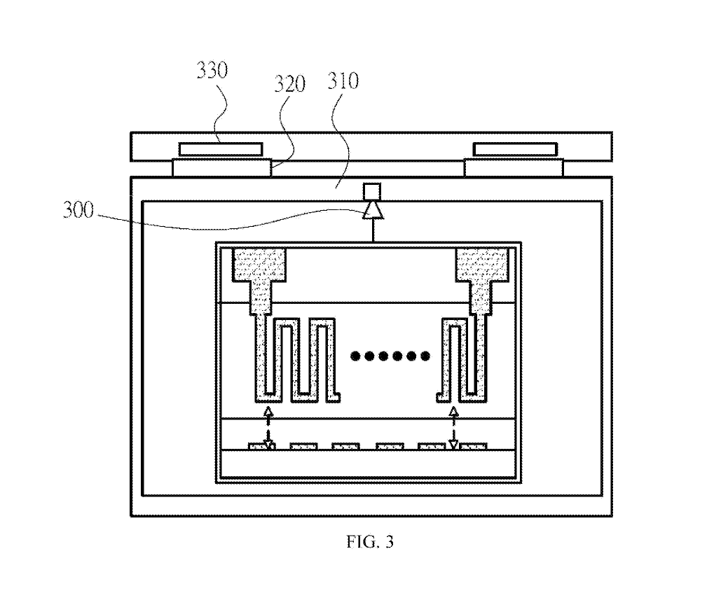

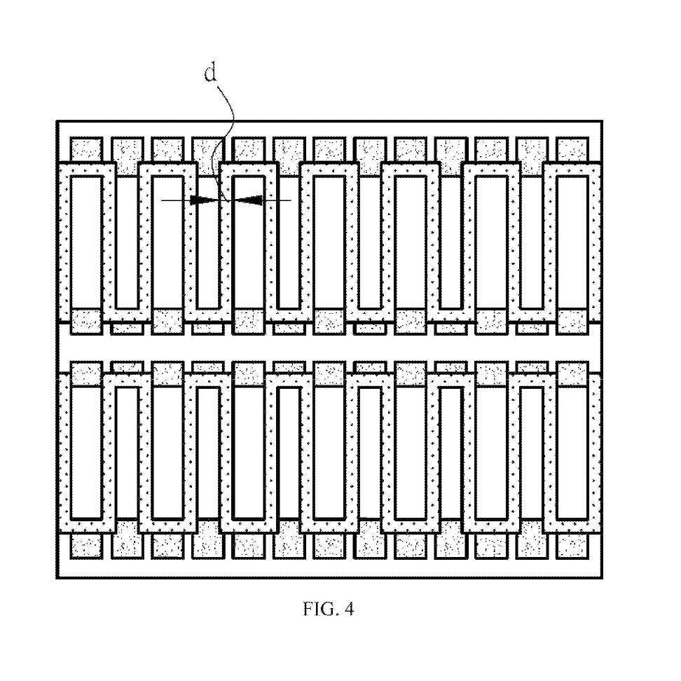

FIG. 3 is a schematic diagram of a liquid crystal display panel integrated with a metal-sheet type thermally sensitive sensor according to an embodiment of the present application; and FIG. 4 is a schematic diagram of width of a metal sheet of a fabricated thermally sensitive sensor according to an embodiment of the present application. Please refer to FIG. 3 and FIG. 4 for a liquid crystal display panel 300 integrated with a metal-sheet type thermally sensitive sensor, comprising a black-matrix boundary 310, a flexible circuit board 320, and a drive IC 330, wherein the width d of the metal sheet is 7 um.

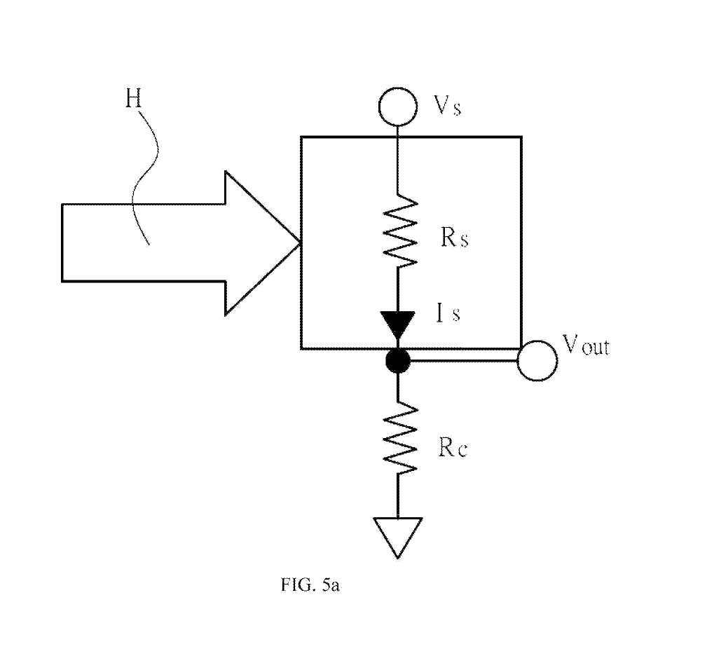

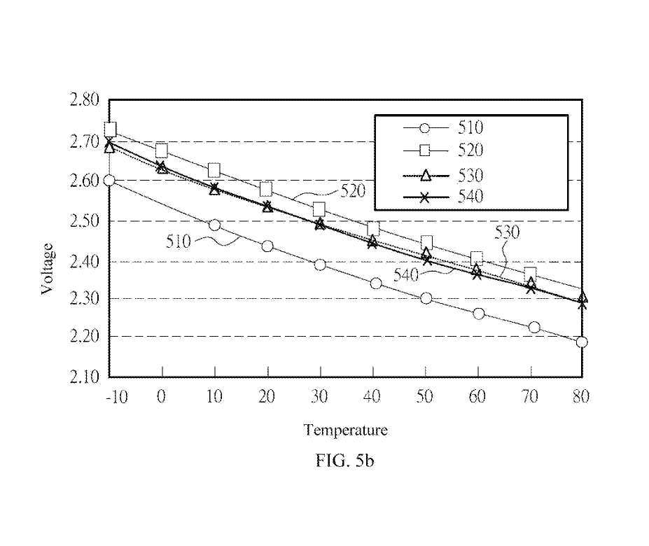

FIG. 5a is a circuit diagram of a thermally sensitive sensor according to an embodiment of the present application; and FIG. 5b is an illustration of experimental output values from four sensors using a voltage-temperature curve according to an embodiment of the present application. Please refer to FIG. 5a and FIG. 5b. The circuit diagram of the thermally sensitive sensor shows Vs (an input voltage)=5 V, Rc (thermally sensitive resistance)=1.6 kΩ, Vout (an output voltage), Rs (resistance), Is (current), and H (heating temperature); and the experimental output values (as shown in FIG. 5b, indicated by the four curves 510, 520, 530, and 540) from four sensors are illustrated using a voltage-temperature curve.

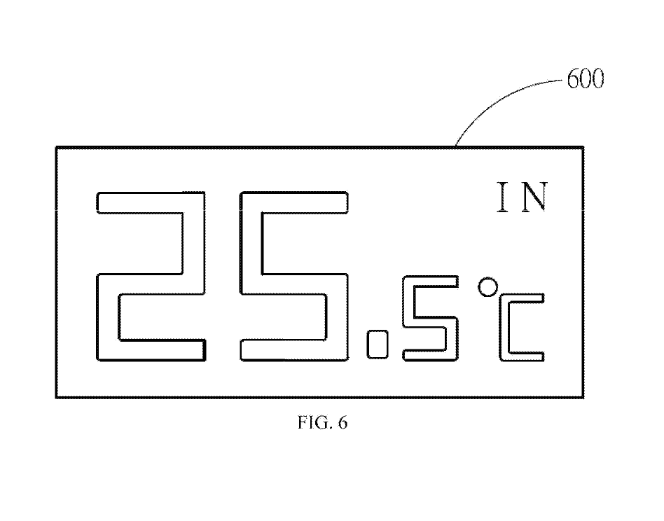

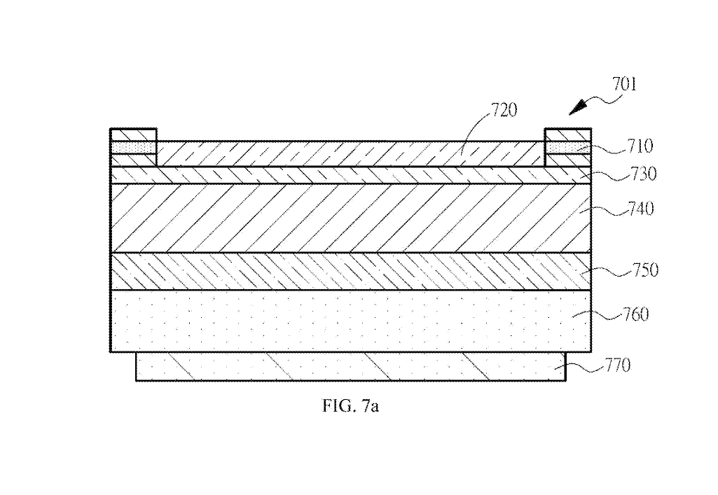

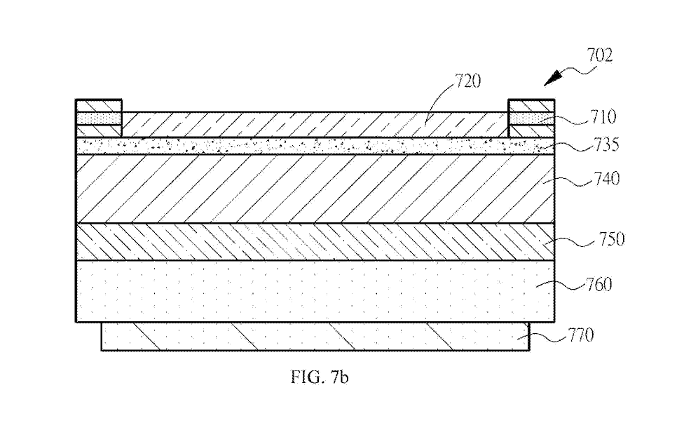

FIG. 6 is a schematic diagram of a temperature display 600 according to an embodiment of the present application; and FIG. 7a is a schematic diagram of a liquid crystal display panel according to an embodiment of the present application. Please refer to FIG. 6 and FIG. 7a for a liquid crystal display panel 701, comprising: a first substrate 740 having an outer surface; a first polarizer 720 disposed on the outer surface of the first substrate 740; a flexible circuit board 710 disposed on the periphery of the first polarizer 720; a second substrate 760 disposed opposite the first substrate 740 and having an outer surface; a second polarizer 770 disposed on the outer surface of the second substrate 760; a temperature sensor 730 disposed on the periphery of the outer surface of the first substrate 740, the temperature sensor 730 being located between the first substrate 740 and the first polarizer 720.

In an embodiment of the present application, the temperature sensor 730 is a metal heater containing indium gallium zinc oxide.

In an embodiment of the present application, the first substrate 740 is a thin film transistor substrate.

In an embodiment of the present application, the second substrate 760 is a color filter substrate.

In an embodiment of the present application, the liquid crystal display panel further comprises a liquid crystal layer 750 disposed between the first substrate 740 and the second substrate 760.

FIG. 7b is a schematic diagram of a liquid crystal display panel according to another embodiment of the present application. Please refer to FIG. 7b for a liquid crystal display panel 702, comprising: a first substrate 740 having an outer surface; a first polarizer 720 disposed on the outer surface of the first substrate 740; a flexible circuit board 710 disposed on the periphery of the first polarizer 720; a second substrate 760 disposed opposite the first substrate 740 and having an outer surface; a second polarizer 770 disposed on the outer surface of the second substrate 760; a temperature sensor 735 disposed on the periphery of the outer surface of the first substrate 740, the temperature sensor 735 being located between the first substrate 740 and the first polarizer 720.

In an embodiment of the present application, the temperature sensor 735 is made of a metal material containing graphene.

In an embodiment of the present application, the first substrate 740 is a thin film transistor substrate.

In an embodiment of the present application, the second substrate 760 is a color filter substrate.

In an embodiment of the present application, the liquid crystal display panel further comprises a liquid crystal layer 750 disposed between the first substrate 740 and the second substrate 760.

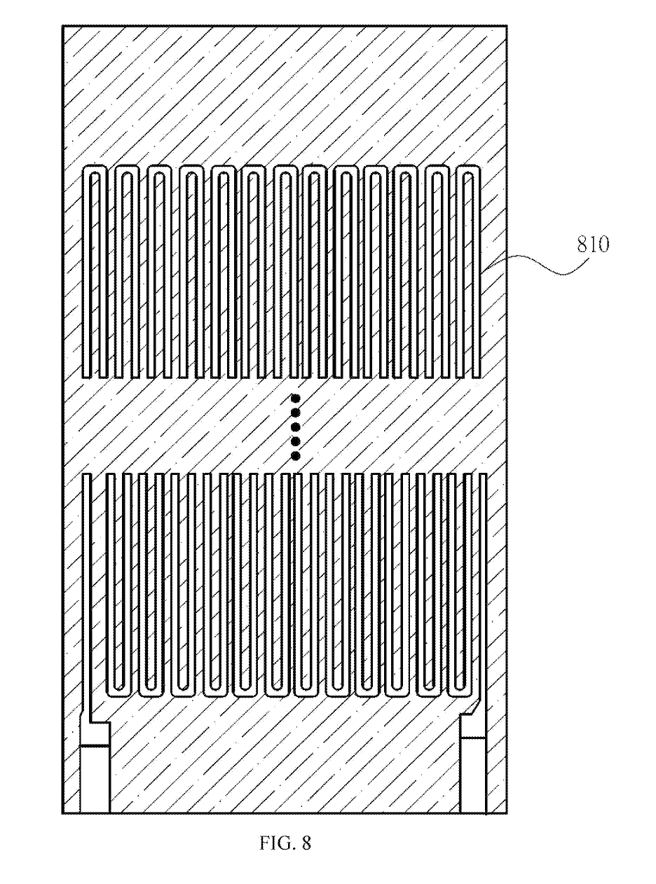

FIG. 8 is a schematic diagram of a resistance according to an embodiment of the present application. Please refer to FIG. 8. A metal arrangement 810 (as shown in FIG. 8) is illustrated.

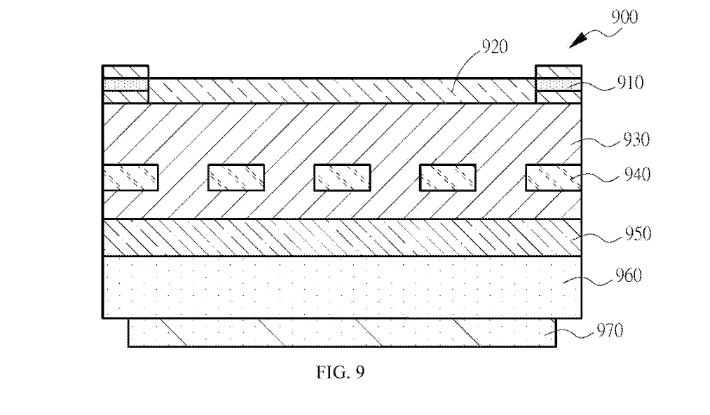

FIG. 9 is a schematic diagram of a liquid crystal display panel according to still another embodiment of the present application. Please refer to FIG. 9 for a liquid crystal display panel 900, comprising: a first substrate 930 having an outer surface; a first polarizer 920 disposed on the outer surface of the first substrate 930; a flexible circuit board 910 disposed on the periphery of the first polarizer 920; a second substrate 960 disposed opposite the first substrate 930 and having an outer surface; a second polarizer 970 disposed on the outer surface of the second substrate 960; and a temperature sensor 940 embedded within the first substrate 930.

In an embodiment of the present application, the temperature sensor 940 is a metal heater containing indium gallium zinc oxide.

In an embodiment of the present application, the first substrate 930 is a thin film transistor substrate.

In an embodiment of the present application, the second substrate 960 is a color filter substrate.

In an embodiment of the present application, the liquid crystal display panel further comprises a liquid crystal layer 950 disposed between the first substrate 940 and the second substrate 960.

A liquid crystal display device, comprising a backlight module (not shown in the figure); a first substrate 930 having an outer surface; a first polarizer 920 disposed on the outer surface of the first substrate 930; a flexible circuit board 910 disposed on the periphery of the first polarizer 920; a second substrate 960 disposed opposite the first substrate 930 and having an outer surface; a second polarizer 970 disposed on the outer surface of the second substrate 960; and a temperature sensor 940 embedded within the first substrate 930.

In an embodiment of the present application, the temperature sensor 940 is a metal heater containing indium gallium zinc oxide.

In an embodiment of the present application, the first substrate 930 is a thin film transistor substrate.

In an embodiment of the present application, the second substrate 960 is a color filter substrate.

In an embodiment of the present application, the liquid crystal display panel further comprises a liquid crystal layer 950 disposed between the first substrate 940 and the second substrate 960.

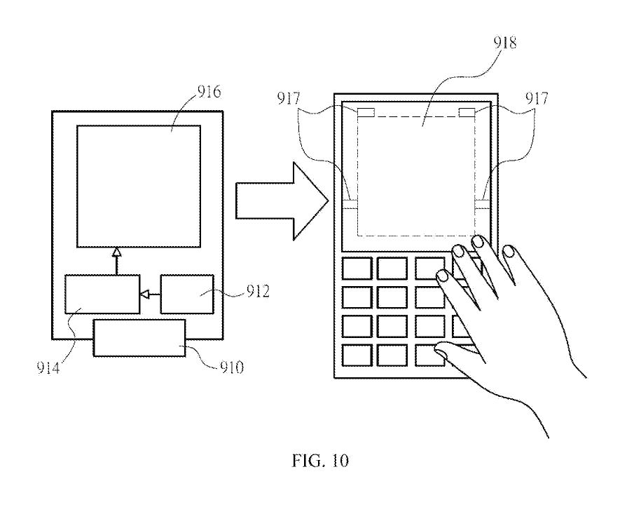

FIG. 10 is a schematic diagram of integrating a temperature sensor into a liquid crystal display according to an embodiment of the present application. Please refer to FIG. 10 for a large-size liquid crystal panel 918, comprising: a flexible circuit board 910, a sensor 912, a liquid crystal driver 914, and a temperature sensor 917. The sensor 912 and the liquid crystal driver 914 are integrated into a temperature sensor 916; and the temperature sensor 916 is arranged at positions 917 on a liquid crystal screen 918. When applied to the large-size panel, the temperature sensor can sense the temperature of different positions on the actual panel; and flicker noise caused by temperature differences can be compensated by a drive voltage based on the measurement result, so as to reduce the noise.

The present application can effectively provide information regarding ambient temperature, and can effectively control the liquid crystal temperature, avoiding delayed liquid crystal response and image retention in a low-temperature environment.

The expressions such as “in some embodiments” and “in various embodiments” are repeatedly used. These expressions generally do not refer to the same embodiments, but may also refer to the same embodiments. The terms such as “comprise”, “have”, and “include” are synonyms, unless the context clearly dictates otherwise.

The above merely describes preferred embodiments of the present application, and is not intended to limit the present application in any way. Although the present application has been disclosed with reference to the preferred embodiments, the present application is not limited thereto. Without departing from the scope of the technical solutions of the present application, any person skilled in the art can make variations or modifications to form equivalent embodiments according to the technical content disclosed above. Any simple variations, equivalent changes and modifications made to the foregoing embodiments according to the technical essence of the present application without departing from the content of the technical solutions of the present application shall fall within the scope of the technical solutions of the present application.

What is claimed is:

1. A liquid crystal display panel, comprising:
a first substrate having an outer surface;
a first polarizer disposed on the outer surface of the first substrate;
a second substrate disposed opposite the first substrate and having an outer surface;
a second polarizer disposed on the outer surface of the second substrate; and
a temperature sensor disposed on the periphery of the outer surface of the first substrate or embedded within the first substrate.

2. The liquid crystal display panel according to claim 1, wherein when the temperature sensor is disposed on the periphery of the outer surface of the first substrate, the temperature sensor is located between the first substrate and the first polarizer.

3. The liquid crystal display panel according to claim 1, wherein the temperature sensor is a metal heater containing indium gallium zinc oxide.

4. The liquid crystal display panel according to claim 1, wherein the temperature sensor is made of a metal material containing graphene.

5. The liquid crystal display panel according to claim 1, wherein the first substrate is a thin film transistor substrate.

6. The liquid crystal display panel according to claim 1, wherein the second substrate is a color filter substrate.

7. The liquid crystal display panel according to claim 1, further comprising a liquid crystal layer disposed between the first substrate and the second substrate.

8. A liquid crystal display device, comprising:
a backlight module; and
a liquid crystal display panel, comprising:
a first substrate having an outer surface;
a first polarizer disposed on the outer surface of the first substrate;
a second substrate disposed opposite the first substrate and having an outer surface;
a second polarizer disposed on the outer surface of the second substrate; and
a temperature sensor disposed on the periphery of the outer surface of the first substrate or embedded within the first substrate,
wherein when the temperature sensor is disposed on the periphery of the outer surface of the first substrate, the temperature sensor is located between the first substrate and the first polarizer.

9. The liquid crystal display device according to claim 8, wherein the temperature sensor is a metal heater containing indium gallium zinc oxide.

10. The liquid crystal display device according to claim 8, wherein the temperature sensor is made of a metal material containing graphene.

11. The liquid crystal display device according to claim 8, wherein the first substrate is a thin film transistor substrate.

12. The liquid crystal display device according to claim 8, wherein the second substrate is a color filter substrate.

13. The liquid crystal display device according to claim 8, wherein the liquid crystal display panel further comprises a liquid crystal layer disposed between the first substrate and the second substrate.

14. A liquid crystal display device, comprising:
a backlight module; and
a liquid crystal display panel, comprising:
a thin film transistor substrate having an outer surface;
a first polarizer disposed on the outer surface of the thin film transistor substrate;
a color filter substrate disposed opposite the thin film transistor substrate and having an outer surface;
a second polarizer disposed on the outer surface of the color filter substrate; and
a temperature sensor disposed on the periphery of the outer surface of the thin film transistor substrate or embedded within the thin film transistor substrate;
wherein the temperature sensor is a metal heater containing indium gallium zinc oxide or is made of a metal material containing graphene; the temperature sensor is disposed on the periphery of the outer surface of the thin film transistor substrate or embedded within the thin film transistor substrate in a continuously bending manner; when the temperature sensor is disposed on the periphery of the outer surface of the thin film transistor substrate, the temperature sensor is located between the thin film transistor substrate and the first polarizer.
